(19) United States
(12) Patent Application Publication
(10) Pub. No.: US 2025/0019817 A1
(43) Pub. Date: Jan. 16, 2025

(54) MASK STRIP AND MASK DEVICE

(71) Applicant: KunShan Go Visionox Opto Electronics Co., Ltd, Kunshan (CN)

(72) Inventors: Bing HAN, Kunshan (CN); Chuang CHEN, Kunshan (CN); Weili LI, Kunshan (CN); Yue QIU, Kunshan (CN); Wenxing LI, Kunshan (CN)

(73) Assignee: KunShan Go Visionox Opto Electronics Co., Ltd, Kunshan (CN)

(21) Appl. No.: 18/901,316

(22) Filed: Sep. 30, 2024

(30) Foreign Application Priority Data
Oct. 20, 2023 (CN) 202311369379.9

(51) Int. Cl. C23C 14/04

(52) U.S. Cl. CPC C23C 14/042

(57) ABSTRACT

A mask strip and a mask device are provided. The mask strip includes a body part, the body part includes two connecting ends arranged in a first direction, the body part further includes at least two evaporation region sets, the evaporation region sets are located between the two connecting ends, each of the evaporation region sets includes at least one evaporation region, each of the evaporation regions includes a plurality of evaporation openings, a number density of the evaporation openings within each of the evaporation regions is a predetermined density, and the predetermined density within any one of the evaporation regions of the evaporation region sets located adjacent to a middle position of the mask strip in the first direction is larger than the predetermined density of any one of the evaporation regions of the evaporation region sets located away from the middle position.

### CROSS REFERENCES TO RELATED APPLICATIONS

This application claims a priority of Chinese Patent Application No. 202311369379.9, filed on Oct. 20, 2023 and titled by “MASK STRIP AND MASK DEVICE”, which is incorporated herein in its entirety.

### TECHNICAL FIELD

The present application relates to the technical field of display, and in particular to a mask strip and a mask device.

### BACKGROUND

With the development of display technology, the performance requirement for a display device is becoming increasingly high. At present, sub-pixels in an OLED display device are formed by means of evaporation for a mask plate.

However, an existing evaporation mask plate cannot achieve the diversity in evaporation products.

### SUMMARY

Embodiments of the present application provide a mask strip and a mask device. The mask strip includes the evaporation regions with different specifications, so that the uniformity of force distribution at all positions is good, and the quality of tensioning net is good.

In a first aspect, embodiments of the present application provide a mask strip including a body part. The body part includes two connecting ends arranged in a first direction, the body part further includes at least two evaporation region sets, the evaporation region sets are located between the two connecting ends, each of the evaporation region sets includes at least one evaporation region, shapes of at least two of the evaporation regions are different, each of the evaporation regions includes a plurality of evaporation openings, a number density of the evaporation openings within each of the evaporation regions is a predetermined density, and the predetermined density within any one of the evaporation regions of the evaporation region sets located adjacent to a middle position of the mask strip in the first direction is larger than the predetermined density of any one of the evaporation regions of the evaporation region sets located away from the middle position of the mask strip in the first direction.

According to the embodiments of the present application in the first aspect, the predetermined density of the evaporation openings in each of the evaporation regions gradually decreases in the first direction and in a direction from the middle position of the mask strip towards a position away from the middle position of the mask strip;

optionally, a number density of the evaporation regions gradually decreases in the first direction and in the direction from the middle position of the mask strip towards the position away from the middle position of the mask strip.

According to any one of the embodiments of the present application in the first aspect, the mask strip includes a symmetry axis parallel to the first direction, and the evaporation openings are symmetrical with respect to the symmetry axis.

According to any one of the embodiments of the present application in the first aspect, each of the evaporation region sets includes a plurality of evaporation regions arranged in a second direction, the second direction is perpendicular to the first direction, and the predetermined densities of the evaporation regions in the evaporation region sets are the same; or

in the evaporation region sets, a predetermined density of the evaporation regions located adjacent to the middle position of the mask strip in the second direction is larger than a predetermined density of the evaporation regions located away from the middle position of the mask strip in the second direction.

According to any one of the embodiments of the present application in the first aspect, the body part further includes a transition region, the transition region surrounds the evaporation regions, the transition region includes an opening region, the opening region include a first opening region located between adjacent two evaporation regions in the first direction and a second opening region located between adjacent two evaporation regions in a direction perpendicular to the first direction, the first opening region includes first openings, a number density of the first openings is set between the predetermined densities of adjacent two evaporation regions in the first direction, the second opening region includes second openings, a number density of the second openings is set between the predetermined densities of adjacent two evaporation regions in the direction perpendicular to the first direction, or a number density of the second openings is equal to the predetermined densities of adjacent two evaporation regions in the direction perpendicular to the first direction;
optionally, the first opening region includes a plurality of first opening sets arranged in the first direction, each of the first opening sets includes a plurality of first openings, and centers of the plurality of first openings are arranged in the direction perpendicular to the first direction;
optionally, a number density of the first openings in each of the first opening sets gradually decreases in a direction from the middle position of the mask strip towards the connecting ends;
optionally, shapes and sizes of the first openings are the same, and distances between the first openings in different first opening sets are different;
optionally, the second opening region includes a plurality of second opening sets arranged in the first direction, each of the second opening sets includes a plurality of second openings, and centers of the plurality of second openings are arranged in the direction perpendicular to the first direction;
optionally, a number density of the second openings in each of the second opening sets gradually decreases in the direction from the middle position of the mask strip towards the connecting ends;
or optionally, the second opening region includes a plurality of second opening sets arranged in the direction perpendicular to the first direction, each of the second opening sets includes a plurality of second openings, and centers of the plurality of second openings are arranged in the first direction;
optionally, a number density of the second openings in each of the second opening sets gradually decreases in the direction perpendicular to the first direction and in a direction from the middle position of the mask strip towards a position away from the middle position of the mask strip;
optionally, shapes and sizes of the second openings are the same, and distances between the second openings in different second opening sets are different;
optionally, the first openings and the second openings are through holes.

According to any one of the embodiments of the present application in the first aspect, a partition region is provided between the opening region and the evaporation regions, and a thickness of the partition region is less than or equal to a thickness of a region between the evaporation openings and larger than 0;
optionally, an arc-shaped region is provided in a boundary between the partition region and the opening region, each of the evaporation regions includes a sharp corner portion, and the arc-shaped region is opposite to the sharp corner portion;
optionally, the mask strip includes an edge region, the edge region is located on two sides of the evaporation region sets and the transition region in the direction perpendicular to the first direction, the edge region is connected to the connecting ends, and a thickness of the edge region is equal to the thickness of the region between the evaporation openings.

According to any one of the embodiments of the present application in the first aspect, the transition region includes an edge transition region located between the evaporation region sets and the connecting ends in the first direction, the edge transition region includes third openings, the third openings are arranged in an array, a size of each of the third openings in the first direction is a first size, a size of each of the third openings in a direction perpendicular to the first direction is a second size, and the first size is larger than the second size; optionally, a ratio of the first size to the second size is larger than 5;
optionally, a shape of each of the third openings is a rectangle.

According to any one of the embodiments of the present application in the first aspect, a shape of each of the evaporation regions includes circle, rectangle, rounded rectangle, elliptic, parallelogram or arrow.

In a second aspect, embodiments of the present application provide a mask device including the mask strip according to any one of embodiments in the first aspect.

According to the embodiments of the present application in the second aspect, the mask device further includes a support plate, the support plate includes an opening opposite to the evaporation regions in the mask strip, and an orthographic projection of the opening on the mask strip is located within the evaporation regions; or the mask device further includes a support strip, a portion of the support strip extends in the first direction, another portion of the support strip extends in a direction perpendicular to the first direction, and an orthographic projection of the support strip on the mask strip does not overlap with the evaporation regions;
optionally, a shape of the opening is different from the shape of each of the evaporation regions.

### BRIEF DESCRIPTION OF THE DRAWINGS

In order to more clearly illustrate the technical solutions of the embodiments of the present application, the drawings to be used in the description of the embodiments of the present application will be described briefly below. Obviously, the drawings in the following description are merely some embodiments of the present application. For those skilled in the art, other drawings can also be obtained according to these drawings without the inventive labor.

FIG. 1 is a structural schematic view of a mask strip according to an embodiment of the present application;

FIG. 2 is a structural schematic view of another mask strip according to an embodiment of the present application;

FIG. 3 is a structural schematic view of a mask strip according to an embodiment of the present application;

FIG. 4 is an enlarged view of region Pin FIG. 3;

FIG. 5 is a structural schematic view of a first opening region in FIG. 4;

FIG. 6 is a structural schematic view of a second opening region in FIG. 4;

FIG. 7 is another structural schematic view of a second opening region in FIG. 4;

FIG. 8 is a structural schematic view of another mask strip according to an embodiment of the present application;

FIG. 9 is a structural schematic view of another mask strip according to an embodiment of the present application;

FIG. 10 is a structural schematic view of an edge transition region in another mask strip according to an embodiment of the present application;

FIG. 11 is a structural schematic view of a mask strip according to an embodiment of the present application;

FIG. 12 is a structural schematic view of a support plate in a mask device according to an embodiment of the present application; and

FIG. 13 is a structural schematic view of another mask device according to an embodiment of the present application.

In the drawings:
1—mask strip; 10—body part; 11—connecting end; X—first direction; 12—evaporation region set; 121—evaporation region; 1211—evaporation opening; 13—transition region; L—symmetry axis; 14—opening region; 141—first opening region; 1410—first opening set; 1411—first opening; 142—second opening region; 1420—second opening set; 1421—second opening; 15—partition region; 16—arc-shaped region; C—sharp corner portion; 17—edge transition region; 171—third opening; D1—first size; D2—second size; 18—marginal region; 2—mask device; 21—support plate; 211—opening; 22—support strip.

### DETAILED DESCRIPTION

Features and exemplary embodiments in various aspects of the present application will be described in detailed below. To make the objects, technical solutions and advantages of the present disclosure to be more apparent, the present disclosure will be further described in detail below with reference to the accompanying drawings and specific embodiments. It shall be understood that the specific embodiments described herein are only to be construed as illustrative and not limiting. To those skilled in the art, the present application can be implemented without some of the specific details. The description of embodiments below is intended merely to provide a better understanding of the present application by showing examples of the present application.

It shall be noted that, in this context, relational terms such as first and second are merely used to distinguish one entity or operation from another entity or operation, and do not necessarily require or imply any such actual relationship or order between the entities or operations. Further, the term “comprise”, “include” or any other variations thereof is intended to encompass a non-exclusive inclusion, such that a process, method, article, or device including a plurality of elements includes not only these elements but also other elements not listed, or elements that are inherent to such process, method, article or device. Without more limitations, an element that is defined by an expression “comprises . . . ”, does not exclude other identical elements in the process, method, article, or device including this element.

In order to better understand the present application, a mask strip and a mask device according to embodiments of the present application will be described in detail below with reference to FIG. 1 to FIG. 13.

Referring to FIG. 1, embodiments of the present application provide a mask strip 1, which includes a body part 10. The body part 10 includes two connecting ends 11 which are arranged in a first direction x. The body part 10 further includes at least two evaporation region sets 12. The evaporation region sets 12 are located between the two connecting ends 11, and each of the evaporation region sets 12 includes at least one evaporation region 121. Shapes of at least two of the evaporation regions 121 are different. Each of the evaporation regions 121 includes a plurality of evaporation openings 1211, and a number density of the evaporation openings 1211 in each of the evaporation regions 121 is a predetermined density. The predetermined density within any one of the evaporation regions 121 of the evaporation region sets 12 located adjacent to a middle position of the mask strip 1 in the first direction x is larger than the predetermined density of any one of the evaporation regions 121 of the evaporation region sets 12 located away from the middle position of the mask strip 1 in the first direction X.

It can be understood that the plurality of evaporation openings 1211 can be uniformly distributed within each of the evaporation regions 121.

The mask strip 1 provided by the present application includes the body part 10, which includes the connecting ends 11 and the evaporation region sets 12. Among them, there are two connecting ends 11 arranged in the first direction x. The connecting ends 11 are used to fix the mask strip 1 to a clamping jaw during tensioning net, so as to support and fix the mask strip 1. Each of the evaporation region sets 12 includes at least one evaporation region 121, and the evaporation regions 121 correspond to display regions of a display panel, respectively. Shapes and areas of different evaporation regions 121 can be the same or different, and the shapes of at least two of the evaporation regions 121 are different. Each of the evaporation regions 121 includes the plurality of evaporation openings 1211, and the number density of evaporation openings 1211 in each of the evaporation regions 121 is the predetermined density. The predetermined density within any one of the evaporation regions 121 of the evaporation region sets 12 located adjacent to a middle position of the mask strip 1 in the first direction x is larger than the predetermined density of any one of the evaporation regions 121 of the evaporation region sets 12 located away from the middle position of the mask strip 1 in the first direction x, which can solve the problem that the force at the connecting ends 11 adjacent to the clamping jaw is different from the force at the middle position of the mask strip 1, improve the uniformity of force distribution at all positions inside the mask strip 1, solve the problem of the deformation such as wrinkles inside the mask strip 1, avoid the poor tensioning net of the mask strip 1, and effectively improve the evaporation yield of the mask strip 1. The mask strip 1 provided by the present application is provided with the plurality of evaporation regions 121 with different specifications. The different specifications mean different shapes and different predetermined densities of the evaporation openings 1211, thereby achieving the diversity of evaporation products. Among the plurality of evaporation regions 121, a portion of the evaporation regions with a relatively low predetermined density is arranged adjacent to the connecting ends 11, so as to avoid the poor tensioning net caused by that the force at the connecting ends 11 adjacent to a connecting and fixing position, such as the clamping jaw, is different from the force at the middle position of the mask strip 1, improve the uniformity of force distribution at all positions inside the mask strip 1, and improve the quality of tensioning net.

In a feasible embodiment, the predetermined density of the evaporation openings 1211 in each of the evaporation regions 121 gradually decreases in the first direction x and in a direction from the middle position of the mask strip 1 towards a position away from the middle position of the mask strip 1. Specifically, in the first direction x, the predetermined density of the evaporation openings 1211 gradually decreases in a direction from the middle position of the mask strip towards the connecting end 11.

Specifically, the evaporation openings 1211 are openings for the evaporation material to pass through and evaporate onto the display regions, so as to form sub pixels within the display panel.

Specifically, the number density of the evaporation openings 1211 in each of the evaporation regions 121 is the number of evaporation openings 1211 per unit area.

In a feasible embodiment, a number density of the evaporation regions 121 gradually decreases in the first direction x and in the direction from the middle position of the mask strip 1 towards the position away from the middle position of the mask strip 1.

Since the position of the mask strip 1 away from the middle position is more affected by a clamping force than the position adjacent to the middle position of mask strip 1, a relatively low number density of the evaporation regions 121 can be set to increase an area of a region between the evaporation regions 121, so as to improve the stress sharing effect of this region, reduce the influence of stress on the evaporation regions 121, and improve the flatness of a region of the mask strip 1 adjacent to the connecting ends 11.

In the above embodiments, the number density of evaporation regions 121 is the number of evaporation regions 121 per unit area.

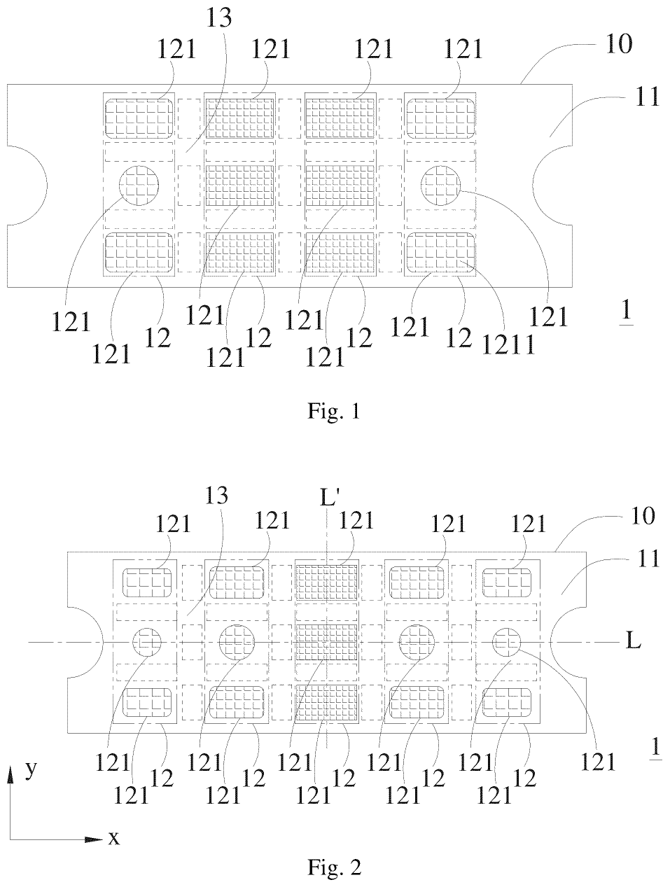

In the above embodiment, as shown in FIG. 1, the number of evaporation region sets 12 in the first direction x may be an even number, or as shown in FIG. 2, the number of evaporation region sets 12 in the first direction x may be an odd number. The present application does not specifically limit this.

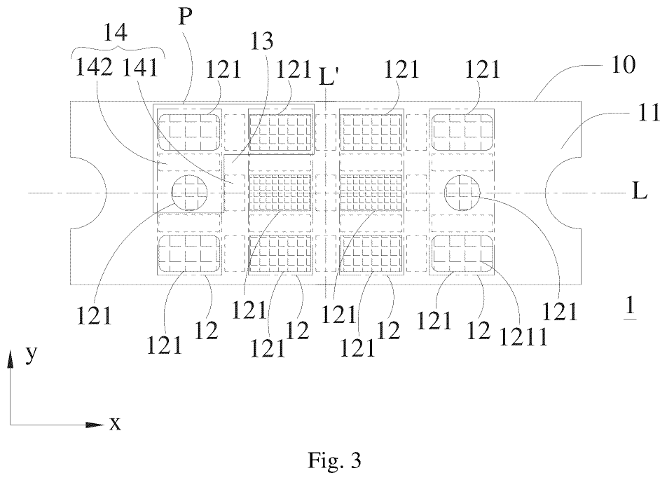

In a feasible embodiment, as shown in FIG. 3, the mask strip 1 includes a symmetry axis L parallel to the first direction x, and the evaporation openings 1211 are symmetrical with respect to the symmetry axis L.

In the above embodiment, the evaporation openings 1211 are symmetrical with respect to the symmetry axis L parallel to the first direction x, so as to ensure the uniformity of stress distribution on two sides of the symmetry axis L, solve the problem of uneven stress distribution during tensioning net, and improve the quality of tensioning net.

Specifically, under the action of tension, inward shrinkages of the mask strip 1 on two sides of the symmetry axis L can be ensured to be consistent, thereby reducing the stress difference between two portions of the mask strip 1 located on two sides of the symmetry axis L.

In a feasible embodiment, the evaporation region set 12 merely includes a row of evaporation regions 121 arranged in the first direction x.

In a feasible embodiment, as shown in FIG. 1 and FIG. 2, the evaporation region set 12 includes a plurality of evaporation regions 121 arranged in a second direction y, the second direction y is perpendicular to the first direction x, and the predetermined densities of the evaporation regions 121 in the evaporation region set 12 are the same.

In the above embodiment, the predetermined densities of the evaporation regions 121 in the evaporation region set 12 are the same, so that the uniformity of stress distribution of the mask strip 1 in the second direction y can be improved, the consistency of internal shrinkage within the same evaporation region set 12 under the tensioning-net force in the first direction x can be ensured, the problem of uneven stress distribution during tensioning net can be solved, and the quality of tensioning net can be improved.

In another feasible embodiment, as shown in FIG. 3, in the evaporation region set 12, a predetermined density of the evaporation regions 121 located adjacent to the middle position of the mask strip 1 in the second direction y is larger than a predetermined density of the evaporation regions 121 located away from the middle position of the mask strip 1 in the second direction y.

In the above embodiment, in the evaporation region set 12, the predetermined density of the evaporation regions 121 located adjacent to the middle position of the mask strip 1 in the second direction y is larger than the predetermined density of the evaporation regions 121 located away from the middle position of the mask strip 1 in the second direction y. The predetermined density of the evaporation regions 121 along an edge perpendicular to the first direction x is relatively low, so as to increase the density of a body located between the evaporation regions 121 in the mask strip 1, improve the attaching effect between the edge perpendicular to the first direction x and a substrate under a magnetic force, improve the alignment accuracy of the evaporation openings 1211, and improve the evaporation yield. Specifically, the mask strip 1 is arranged on a side of the substrate facing away from a magnet plate during use. Under the magnetic force provided by the magnet plate, the mask strip 1 is attached to a surface of the substrate. The expression “attached” refers to the contact between the mask strip 1 and the surface of the substrate. The closer the contact is and the smaller a gap is, the better the attachment effect is.

According to the arrangement, the stress distribution can be more uniform, the density of openings at the edge can be low, the density of the metal material can increase, and the attaching effect between the edge and glass under the action of the magnetic plate can be improved.

In a feasible embodiment, as shown in FIG. 2 and FIG. 3, the mask strip 1 includes another symmetry axis L′ perpendicular to the first direction x, and the evaporation region set 12 is symmetrical with respect to the symmetry axis L′, so as to improve the uniformity of stress distribution on two sides of the symmetry axis L′, solve the problem of uneven stress distribution during tensioning net, and improve the quality of tensioning net.

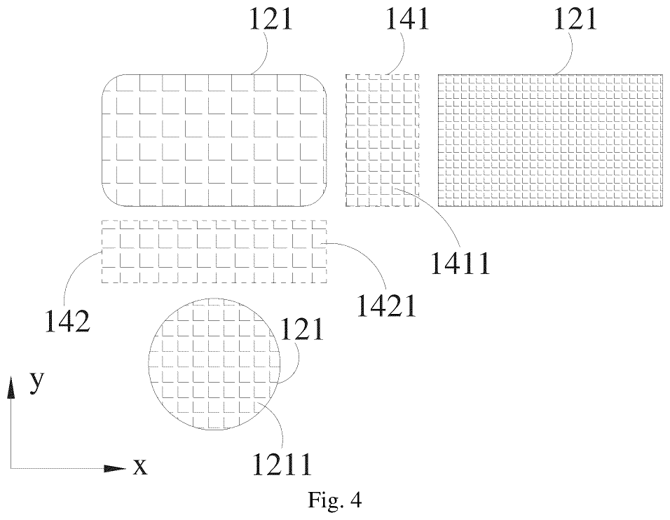

In a feasible embodiment, as shown in FIG. 3 and FIG. 4, the body part 10 further includes a transition region 13, the transition region 13 surrounds the evaporation regions 121, the transition region 13 includes an opening region 14, the opening region 14 includes a first opening region 141 located between adjacent two evaporation regions 121 in the first direction x and a second opening region 142 located between adjacent two evaporation regions 121 in a direction perpendicular to the first direction x, the first opening region 141 includes first openings 1411, a number density of the first openings 1411 is set between the predetermined densities of adjacent two evaporation regions 121 in the first direction x, the second opening region 142 includes second openings 1421, a number density of the second openings 1421 is set between the predetermined densities of adjacent two evaporation regions 121 in the direction perpendicular to the first direction x.

In the above embodiment, the transition region 13 is arranged around the evaporation regions 121 to separate adjacent evaporation regions 121 and form the opening region 14 between adjacent two evaporation regions 121, which can reduce the stress difference between the transition region 13 and the evaporation regions 121. In addition, a transition design of the predetermined density between adjacent evaporation regions 121 can be achieved through the first opening 1411 and/or the second opening 1421, thereby improving the uniformity of stress distribution of the mask strip 1.

Specifically, a width of a portion of the transition region 13 located between adjacent two evaporation regions 121 is larger than a distance between any adjacent two evaporation openings 1211 within the same evaporation region 121, and the width of the portion of the transition region 13 located between adjacent two evaporation regions 121 is larger than the sum of widths of borders of the display panel corresponding to adjacent two evaporation regions 121.

In the above embodiment, the first opening region 141 is provided between adjacent two evaporation regions 121 in the first direction x. The number density of the first openings 1411 is set between the predetermined densities of adjacent two evaporation regions 121 in the first direction x. Therefore, the predetermined density of the entire mask strip 1 and the number density of the first openings 1411 gradually decrease in the direction from the middle position of the mask strip 1 towards the connecting end 11. Specifically, in the adjacent evaporation regions 121 and the first opening region 141, when the evaporation regions 121 is located on the side of the first opening region 141 close to the middle position in the first direction x, the predetermined density of the evaporation regions 121 is larger than the number density of the first openings 1411 in the first opening region 141; the evaporation regions 121 is located on the side of the first opening region 141 away from the middle position in the first direction x, the predetermined density of the evaporation regions 121 is less than the number density of the first openings 1411 in the first opening region 141. Therefore, the predetermined density of the evaporation regions 121 of the mask strip 1 and the number density of the first openings 1411 in the transition region 13 gradually decrease in the direction from the middle position towards the connecting end 11 in the first direction x, so as to solve the problem of the uneven stress distribution caused by that the force at the connecting ends 11 adjacent to the clamping jaw is different from the force at the middle position of the mask strip 1, improve the uniformity of force distribution at all positions in the mask strip 1, solve the problem of the deformation such as wrinkles inside the mask strip 1, avoid the poor tensioning net of the mask strip 1, and effectively improve the evaporation yield of the mask strip 1.

In the above embodiment, the second opening region 142 is provided between adjacent two evaporation regions 121 in the second direction y. The number density of the second openings 1421 is set between the predetermined densities of adjacent two evaporation regions 121 in the direction perpendicular to the first direction x. Therefore, the predetermined density of the entire mask strip 1 and the number density of the second openings 1421 gradually decrease in the direction from the middle position of the mask strip 1 towards two sides in the direction perpendicular to the first direction x. Specifically, in the adjacent evaporation regions 121 and the second opening region 142, when the evaporation regions 121 is located on the side of the second opening region 142 close to the middle position in the direction perpendicular to the first direction x, the predetermined density of the evaporation regions 121 is larger than the number density of the second openings 1421 in the second opening region 142; the evaporation regions 121 is located on the side of the second opening region 142 away from the middle position in the direction perpendicular to the first direction x, the predetermined density of the evaporation regions 121 is less than the number density of the second openings 1421 in the second opening region 142. Therefore, the predetermined density of the evaporation regions 121 of the mask strip 1 and the number density of the second openings 1421 in the transition region 13 gradually decrease in the direction from the middle position towards the connecting end 11 in the first direction x, so as to solve the problem of the uneven stress distribution caused by that the force at the connecting ends 11 adjacent to the clamping jaw is different from the force at the middle position of the mask strip 1, improve the uniformity of force distribution at all positions in the mask strip 1, solve the problem of the deformation such as wrinkles inside the mask strip 1, avoid the poor tensioning net of the mask strip 1, and effectively improve the evaporation yield of the mask strip 1.

Alternatively, when the predetermined densities of adjacent evaporation regions 121 in the second direction y are the same, the number density of the second openings 1421 within the second opening region 142 is the same as the predetermined densities of adjacent two evaporation regions 121 in the direction perpendicular to the first direction x. That is, the number density of the second openings 1421 within the second opening region 142 located between adjacent two evaporation regions 121 in the second direction y is the same as the predetermined density in the evaporation region 121, and it means that the predetermined densities of the adjacent evaporation regions 121 in the second direction y, the predetermined density the second opening region 142 and the number density of the second openings 1421 are the same with one another.

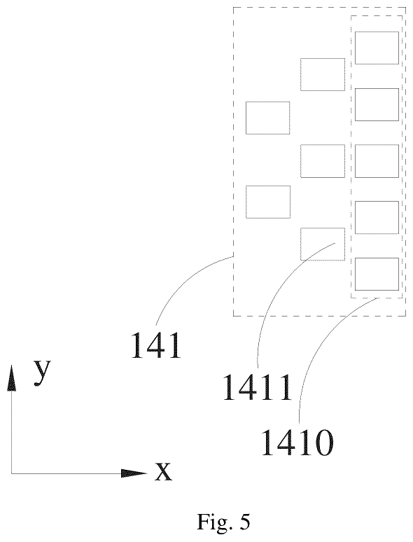

In a feasible embodiment, as shown in FIG. 5, the first opening region 141 includes a plurality of first opening sets 1410 arranged in the first direction x, each of the first opening sets 1410 includes a plurality of first openings 1411, and centers of the plurality of first openings 1411 are arranged in the direction perpendicular to the first direction x.

Specifically, the first opening region 141 includes the plurality of first opening sets 1410 arranged in the first direction x. Each of the first opening sets 1410 includes the plurality of first openings 1411, so that the density variation of the entire first opening region 141 can be controlled by controlling the number density of the first openings 1411 in each of the first opening sets 1410.

Specifically, the centers of the plurality of first openings 1411 are arranged in the direction perpendicular to the first direction x, so that the first openings 1411 can be uniformly distributed in the direction perpendicular to the first direction x, and the stress uniformity in the direction perpendicular to the first direction x can be improved.

In the above embodiment, the number density of the first openings 1411 in each of the first opening sets 1410 gradually decreases in the direction from the middle position of the mask strip 1 towards the connecting end 11, so as to solve the problem of the stress distribution difference of the first opening sets 1410 between the middle position of the mask strip 1 and the position adjacent to the connecting ends 11 caused by the connecting ends 11 adjacent to the clamping jaw, improve the uniformity of force distribution at all positions in the first opening sets 1410, and reduce the probability of appearing wrinkle in the first opening sets 1410.

In the above embodiments, shapes and sizes of the first openings 1411 are the same, and distances between the first openings 1411 in different first opening sets 1410 are different, so as to control the number density of the first openings 1411 in the first opening sets 1410 by controlling the distance between the first openings 1411, and simplify the operation.

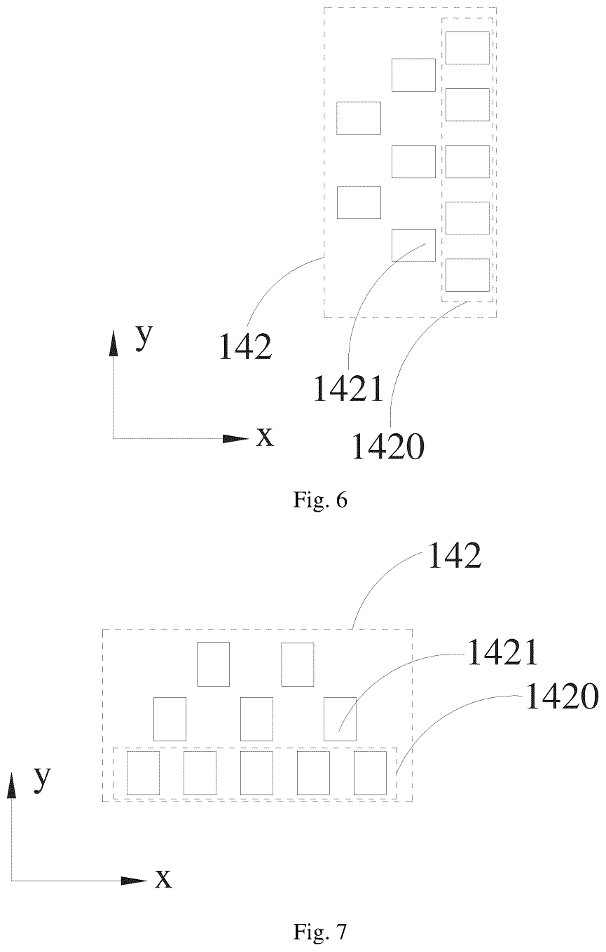

In a feasible embodiment, as shown in FIG. 6, the second opening region 142 includes a plurality of second opening sets 1420 arranged in the first direction x, each of the second opening set 1420 includes a plurality of second openings 1421, and centers of the plurality of second openings 1421 are arranged in the direction perpendicular to the first direction x.

Specifically, the second opening region 142 includes the plurality of second opening sets 1420 arranged in the first direction x. Each of the second opening sets 1420 includes the plurality of second openings 1421, so that the density variation of the entire second opening region 142 can be controlled by controlling the number density of the second openings 1421 in each of the second opening sets 1420.

Specifically, the centers of the plurality of second openings 1421 are arranged in the direction perpendicular to the first direction x, so that the second openings 1421 can be uniformly distributed in the direction perpendicular to the first direction x, and the stress uniformity in the direction perpendicular to the first direction x can be improved. In the above embodiment, the number density of the second openings 1421 in each of the second opening sets 1420 gradually decreases in the direction from the middle position of the mask strip 1 towards the connecting end 11, so as to solve the problem of the stress distribution difference of the second opening sets 1420 between the middle position of the mask strip 1 and the position adjacent to the connecting ends 11 caused by the connecting ends 11 adjacent to the clamping jaw, improve the uniformity of force distribution at all positions in the second opening sets 1420, and reduce the probability of appearing wrinkle in the second opening sets 1420.

Specifically, this embodiment can be used in a situation that the predetermined densities of the evaporation regions 121 in the evaporation region set 12 are the same in the direction perpendicular to the first direction x, or in the evaporation region set 12, the predetermined density of the evaporation region 121 adjacent to the middle position of the mask strip 1 in the second direction y is larger than the predetermined density of the evaporation region 121 away from the middle position of the mask strip 1 in the second direction y. The number density of the second openings 1421 in each of the second opening sets 1420 gradually decreases in the direction from the middle position of the mask strip 1 towards the connecting end 11, so as to solve the problem of the stress distribution difference of the second opening sets 1420 between the middle position of the mask strip 1 and the position adjacent to the connecting ends 11 caused by the connecting ends 11 adjacent to the clamping jaw.

In a feasible embodiment, as shown in FIG. 7, the second opening region 142 includes a plurality of second opening sets 1420 arranged in the direction perpendicular to the first direction x, each of the second opening sets 1420 includes a plurality of second openings 1421, and centers of the plurality of second openings 1421 are arranged in the first direction x.

Specifically, the second opening region 142 includes the plurality of second opening sets 1420 arranged in the direction perpendicular to the first direction x, each of the second opening sets 1420 includes the plurality of second openings 1421, so that the density variation of the entire second opening region 142 can be controlled by controlling the number density of the second openings 1421 in each of the second opening sets 1420.

Specifically, the centers of the plurality of second openings 1421 are arranged in the first direction x, so that the second openings 1421 can be uniformly distributed in the first direction x, and the stress uniformity in the first direction x can be improved.

Specifically, the number density of the second openings 1421 in the second opening set 142 gradually decreases in the direction perpendicular to the first direction x and in the direction from the position adjacent to the middle position of the mask strip 1 towards the position away from the middle position of the mask strip 1. This embodiment can be used in a situation that in the evaporation region set 12, the predetermined density of the evaporation region 121 adjacent to the middle position of the mask strip 1 in the second direction y is larger than the predetermined density of the evaporation region 121 away from the middle position of the mask strip 1 in the second direction y. The number density of the second openings 1421 in the second opening set 142 gradually decreases in the direction perpendicular to the first direction x and in the direction from the position adjacent to the middle position of the mask strip 1 towards the position away from the middle position of the mask strip 1, so as to achieve the number density variation of the second openings 1421 located in the region between adjacent evaporation regions 121 in the direction perpendicular to the first direction x, which is the same as the predetermined density variation between the adjacent evaporation regions 121, and achieve the transition between the evaporation regions 121 in the direction perpendicular to the first direction x.

In the above embodiment, the shapes and the sizes of the second openings 1421 are the same, and the distances between the second openings 1421 in different second opening sets 1420 are different, so as to control the number density of the second openings 1421 in the second opening sets 1420 by controlling the distance between the second openings 1421, and simplify the operation.

Specifically, the first opening 1411 and the second opening 1421 are through holes. Thus, the difference among the first opening 1411, the second opening 1421 and the evaporation opening 1211 can be reduced, so as to improve the uniformity of stress distribution in the mask strip 1.

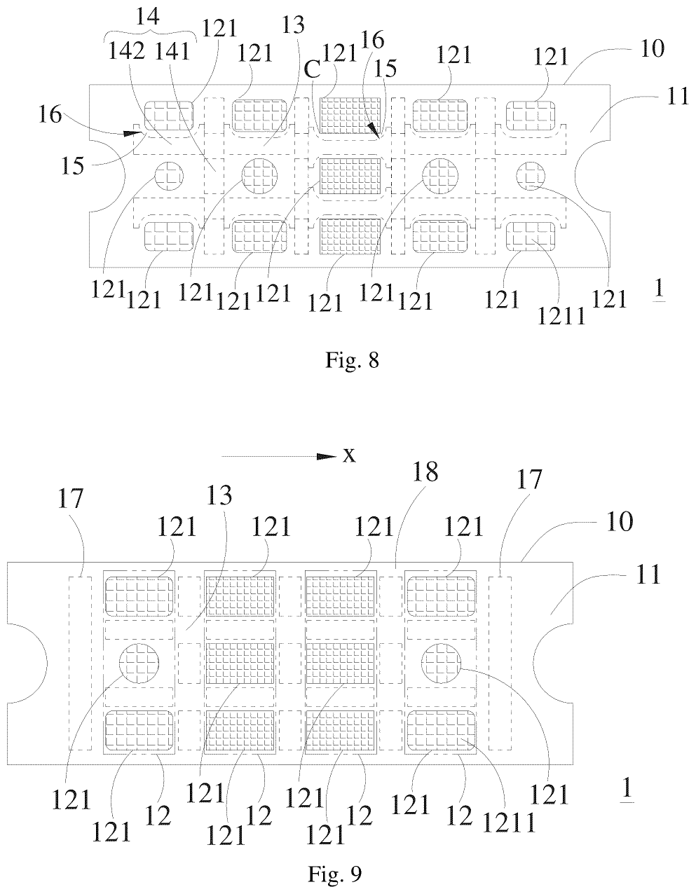

In a feasible embodiment, as shown in FIG. 8, a partition region 15 is provided between the opening region 14 and the evaporation regions 121, and a thickness of the partition region 15 is less than or equal to a thickness of a region between the evaporation openings 1211 and larger than 0.

In the above embodiment, by forming the partition region between the opening region 14 and the evaporation regions 121, the support effect of the mask strip 1 can be improved.

When a thickness of the partition region 15 is less than a thickness of the region between the evaporation openings 1211 and is larger than 0, the partition region 15 can improve the extensibility around the evaporation regions 121 and prevent the wrinkles from extending in the first direction x.

Specifically, the partition region 15 can be a non-etched region or a semi-etched region of the body part 10 based on an original thickness, which is conducive to manufacturing, and the present application specifically does not limit an etching depth.

Optionally, the partition region 15 can be the semi-etched region of the body part 10 based on an original thickness, so that the manufactured partition region 15 can further reduce the extension of the wrinkles.

In a feasible embodiment, an arc-shaped region 16 is provided in a boundary between the partition region 15 and the opening region 14, each of the evaporation regions 121 includes a sharp corner portion C, and the arc-shaped region 16 is opposite to the sharp corner portion C. The arc-shaped region 16 can prevent the uneven stress from entering into the evaporation regions 121, thereby improving the evaporation yield of the evaporation regions 121.

In a feasible embodiment, as shown in FIG. 9, the mask strip 1 includes an edge region 18, the edge region 18 is located on two sides of the evaporation region sets 12 and the transition region 13 in the direction perpendicular to the first direction x, the edge region 18 is connected to the connecting ends 11, and a thickness of the edge region 18 is equal to the thickness of the region between the evaporation openings 1211.

In the above embodiment, by setting the thickness of the edge region 18 to an original thickness of the body part 10, the support effect can be improved, the good contact effect between the edge region 18 and the support strip 22 used to support the mask strip 1 can be maintained, the probability of occurring offset of the evaporation openings 1211 caused by the curvature of the edge region 18 can be reduced, the evaporation yield can be effectively improved, and especially the evaporation openings 1211 adjacent to the edge region 18 can be effectively improved.

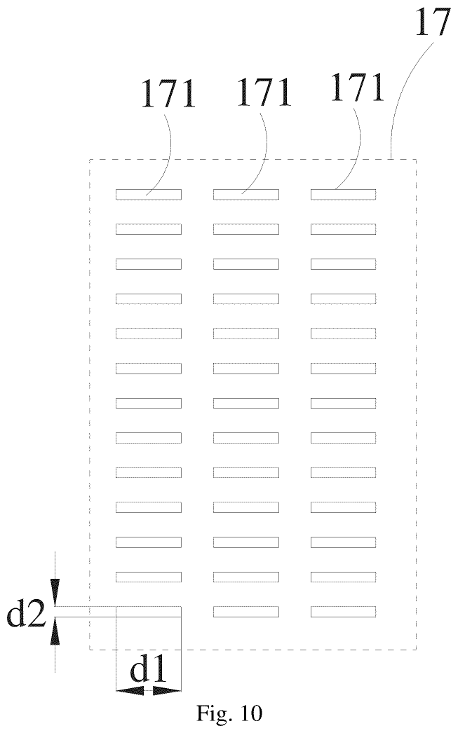

In a feasible embodiment, as shown in FIG. 9 and FIG. 10, the transition region 13 includes an edge transition region 17 located between the evaporation region sets 12 and the connecting ends 11 in the first direction, the edge transition region 17 includes third openings 171, the third openings 171 are arranged in an array, a size of each of the third openings 171 in the first direction x is a first size d1, a size of each of the third openings 171 in a direction perpendicular to the first direction x is a second size d2, and the first size d1 is larger than the second size d2.

In the above embodiment, the third openings 171 are provided within the edge transition region 17. The stress is transmitted from the connecting end 11 through a body position located between the third openings 171, and cannot be transmitted at the third openings 171, so that the stress of the connecting end 11 which is transmitted to the evaporation region set 12 through the third openings 171 can be reduced. In addition, each of the third openings 171 can block the wrinkle continuously generated on two sides of the third opening 171 in the first direction x, thereby reducing the probability of the wrinkle close to the connecting end 11 being transmitted to the evaporation regions 121, and improving the yield of tensioning net.

In the above embodiment, the first size d1 is larger than the second size d2, which can allow the stress to be transmitted along the relatively long body between the third openings 171 and improve the support strength in the first direction x.

Specifically, a ratio of the first size d1 to the second size d2 is larger than 5.

Specifically, the ratio of the first size d1 to the second size d2 may be 5.1, 5.3, 5.5, 6 or the like, and the present application does not specifically limit this.

Specifically, the shape of the third opening 171 includes the rectangle, which can allow sizes of the body of the mask strip 1 located between the third openings 171 in the first direction x and in the direction perpendicular to the first direction x more uniform, and allow the stress at the body position more uniform.

In a feasible embodiment, as shown in FIG. 9, a shape of each of the evaporation regions 121 includes circle, rectangle, rounded rectangle, elliptic, parallelogram or arrow. The mask strip 1 provided by the present application can be applied to the display panel with the display regions in shape of circle, rectangle, rounded rectangle, elliptic, parallelogram or arrow. The shapes described above are commonly used, or may be other shapes, which are not specifically limited in the present application.

The mask strip 1 provided by the present application can be applied to the display panels with different shapes and different pixel densities, and have a wider applicability. Moreover, the mask strip 1 has a good effect of tensioning net and a high evaporation yield, thereby improving the yield of manufacturing the display panels.

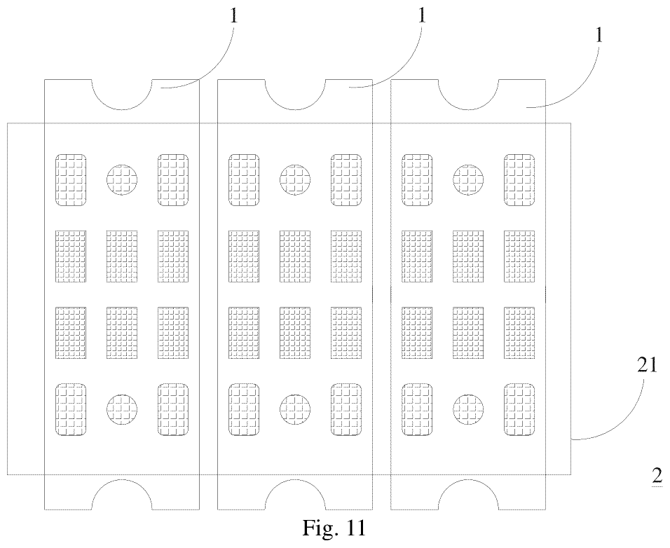

As shown in FIG. 11, the present application provides a mask device 2, including the mask strips 1 according to any one of the above embodiments of the present application.

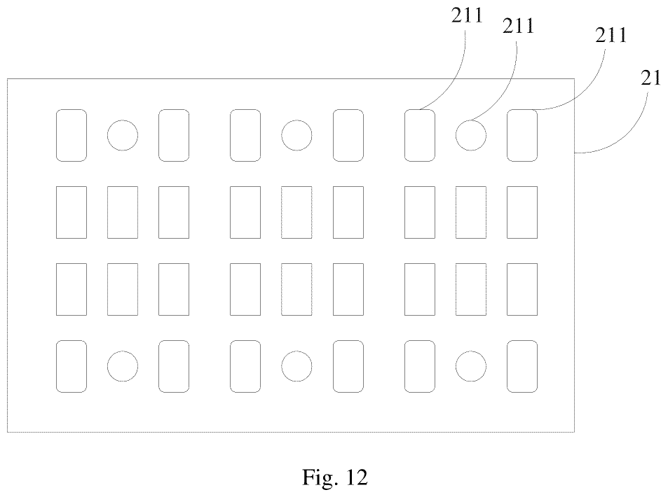

In a feasible embodiment, as shown in FIG. 11 and FIG. 12, the mask device 2 further includes a support plate. The support plate 21 includes an opening 211 opposite to the evaporation regions 121 in the mask strip 1, and an orthographic projection of the opening 211 on the mask strip 1 is located within the evaporation regions 121.

In the above embodiment, the mask strip 1 can be supported by the support plate 21, and one support plate 21 can correspond to a plurality of mask strips 1, that is, the orthographic projection of the mask strip 1 on the support plate 21 is located within the support plate 21.

The support plate 21 includes the opening 211 opposite to the evaporation regions 121 in the mask strip 1, and the orthographic projection of the opening 211 on the mask strip 1 is located with the evaporation regions 121, so that the mask strip 1 can be supported, and the evaporation regions 121 can be blocked by the support plate 21. The shape of the effective evaporation regions 121 of the substrate onto which the evaporation material is evaporated can be set according to the actual situation of the opening 211, and the mask strip 1 can be suitable for manufacturing the display panels in different evaporation regions 121 after being supported by different support plates 21, thereby saving the manufacturing cost of mask strip 1.

In the above embodiment, the shape of the opening 211 may be different from the shape of the evaporation regions 121. Specifically, the shape of the evaporation regions 121 may be the rectangle, and the shape of the opening 211 can be used to block the evaporation regions 121 to form the effective evaporation regions 121 with another shape, such as circle or elliptic. According to this setting, the difficulty of manufacturing the mask strip can be reduced, and the manufacturing process can be simplified.

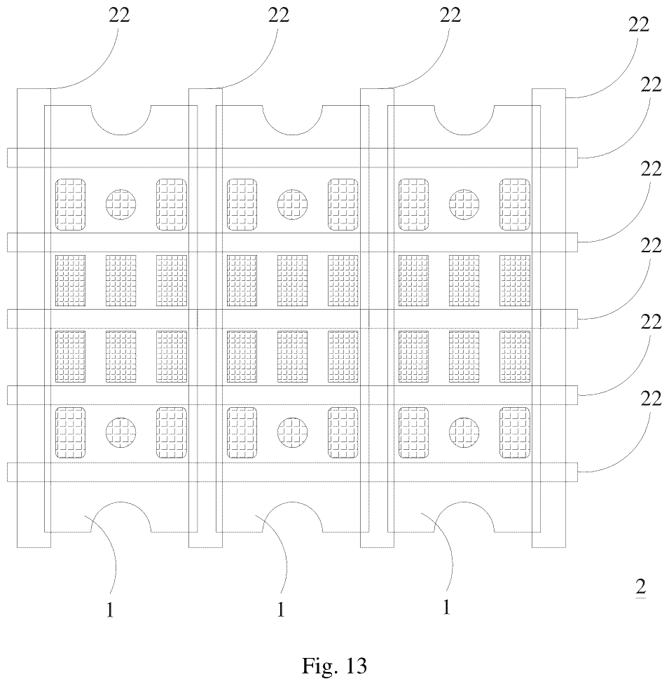

In another feasible embodiment, as shown in FIG. 13, the mask device 2 further includes a support strip 22. A portion of the support strip 22 extends in the first direction x, another portion of the support strip 22 extends in a direction perpendicular to the first direction x, and an orthographic projection of the support strip 22 on the mask strip 1 does not overlap with the evaporation regions 121.

In the above embodiment, the mask strip 1 is supported by the support strips 22 arranged across each other.

It can be understood that the beneficial effects of the mask device 2 can be specifically referred to the beneficial effects of the mask strip 1 as mentioned above, which will not be repeated here.

According to the embodiments described above in the present application, these embodiments do not elaborate on all details and do not limit the application to the specific embodiments. Obviously, based on the above description, various modifications and changes can be made. The present application selects and specifically describes these embodiments in order to better explain the principle and the practical application of the present application, so that those skilled in the art can effectively apply the present application and the modifications based on the present application. The present application is limited only by the claims and their full scope and equivalents.

What is claimed is:

1. A mask strip, comprising a body part, wherein the body part comprises two connecting ends arranged in a first direction, the body part further comprising at least two evaporation region sets, the evaporation region sets being located between the two connecting ends, each of the evaporation region sets comprising at least one evaporation region, shapes of at least two of the evaporation regions being different, each of the evaporation regions comprising a plurality of evaporation openings, a number density of the plurality of evaporation openings within each of the evaporation regions being a predetermined density, and the predetermined density within any one of the evaporation regions of the evaporation region sets located adjacent to a middle position of the mask strip in the first direction being larger than the predetermined density of any one of the evaporation regions of the evaporation region sets located away from the middle position of the mask strip in the first direction.

2. The mask strip according to claim 1, wherein the predetermined density of the plurality of evaporation openings in each of the evaporation regions gradually decreases in the first direction and in a direction from the middle position of the mask strip towards a position away from the middle position of the mask strip.

3. The mask strip according to claim 2, wherein a number density of the evaporation regions gradually decreases in the first direction and in the direction from the middle position of the mask strip towards the position away from the middle position of the mask strip.

4. The mask strip according to claim 1, wherein the mask strip comprises a symmetry axis parallel to the first direction, and the plurality of evaporation openings are symmetrical with respect to the symmetry axis.

5. The mask strip according to claim 4, wherein each of the evaporation region sets comprises a plurality of evaporation regions arranged in a second direction, the second direction is perpendicular to the first direction, and the predetermined densities of the plurality of evaporation regions in each of the evaporation region sets are the same; or
in the evaporation region sets, a predetermined density of the plurality of evaporation regions located adjacent to the middle position of the mask strip in the second direction is larger than a predetermined density of the plurality of evaporation regions located away from the middle position of the mask strip in the second direction.

6. The mask strip according to claim 1, wherein the body part further comprises a transition region, the transition region surrounds the evaporation regions, the transition region comprises an opening region, the opening region comprises a first opening region located between adjacent two evaporation regions in the first direction and a second opening region located between adjacent two evaporation regions in a direction perpendicular to the first direction, the first opening region comprises first openings, a number density of the first openings is set between the predetermined densities of adjacent two evaporation regions in the first direction, the second opening region comprises second openings, a number density of the second openings is set between the predetermined densities of adjacent two evaporation regions in the direction perpendicular to the first direction, or a number density of the second openings is equal to the predetermined densities of adjacent two evaporation regions in the direction perpendicular to the first direction.

7. The mask strip according to claim 6, wherein the first opening region comprises a plurality of first opening sets arranged in the first direction, each of the first opening sets comprises a plurality of first openings, and centers of the plurality of first openings are arranged in the direction perpendicular to the first direction.

8. The mask strip according to claim 6, wherein a number density of the first openings in each of the first opening sets gradually decreases in a direction from the middle position of the mask strip towards the connecting ends.

9. The mask strip according to claim 6, wherein shapes and sizes of the first openings are the same, and distances between the first openings in different first opening sets are different; shapes and sizes of the second openings are the same, and distances between the second openings in different second opening sets are different.

10. The mask strip according to claim 6, wherein the second opening region comprises a plurality of second opening sets arranged in the first direction, each of the second opening sets comprises a plurality of second openings, and centers of the plurality of second openings are arranged in the direction perpendicular to the first direction.

11. The mask strip according to claim 6, wherein a number density of the second openings in each of the second opening sets gradually decreases in a direction from the middle position of the mask strip towards the connecting ends.

12. The mask strip according to claim 6, wherein the second opening region comprises a plurality of second opening sets arranged in the direction perpendicular to the first direction, each of the second opening sets comprises a plurality of second openings, and centers of the plurality of second openings are arranged in the first direction.

13. The mask strip according to claim 6, wherein a number density of the second openings in each of the second opening sets gradually decreases in the direction perpendicular to the first direction and in a direction from the middle position of the mask strip towards a position away from the middle position of the mask strip.

14. The mask strip according to claim 6, wherein a partition region is provided between the opening region and the evaporation regions, and a thickness of the partition region is less than or equal to a thickness of a region between the evaporation openings and larger than 0.

15. The mask strip according to claim 14, wherein an arc-shaped region is provided in a boundary between the partition region and the opening region, each of the evaporation regions comprises a sharp corner portion, and the arc-shaped region is opposite to the sharp corner portion.

16. The mask strip according to claim 14, wherein the mask strip comprises an edge region, the edge region is located on two sides of the evaporation region sets and the transition region in the direction perpendicular to the first direction, the edge region is connected to the connecting ends, and a thickness of the edge region is equal to the thickness of the region between two of the plurality of evaporation openings.

17. The mask strip according to claim 1, wherein the transition region comprises an edge transition region located between the evaporation region sets and the connecting ends in the first direction, the edge transition region comprises a plurality of third openings, the plurality of third openings are arranged in an array, a size of each of the plurality of third openings in the first direction is a first size, a size of each of the plurality of third openings in a direction perpendicular to the first direction is a second size, and the first size is larger than the second size.

18. The mask strip according to claim 1, wherein a shape of each of the evaporation regions comprises circle, rectangle, rounded rectangle, elliptic, parallelogram or arrow.

19. A mask device, comprising the mask strip according to claim 1.

20. The mask device according to claim 19, further comprising a support plate, wherein the support plate comprises at least one opening opposite to the evaporation regions in the mask strip, and an orthographic projection of the opening on the mask strip is located within the evaporation regions; or
further comprising a plurality of support strips, wherein a portion of the plurality of support strips extends in the first direction, another portion of the plurality of support strips extends in a direction perpendicular to the first direction, and an orthographic projection of the plurality of support strips on the mask strip does not overlap with the evaporation regions.
